(19) United States
(12) Patent Application Publication
(10) Pub. No.: US 2025/0210490 A1
(43) Pub. Date: Jun. 26, 2025

(54) PACKAGING ARCHITECTURE FOR PHOTONIC COMPONENTS

(71) Applicant: NOKIA SOLUTIONS AND NETWORKS OY, Espoo (FI)

(72) Inventors: Juthika BASAK, Sunnyvale, CA (US); Abderrahim EL AMRANI, Sunnyvale, CA (US)

(21) Appl. No.: 18/394,399

(22) Filed: Dec. 22, 2023

(51) Int. Cl. H01L 23/498; H01L 23/00; H01L 23/13; H01L 25/18

(52) U.S. Cl. CPC H01L 23/49833; H01L 23/13; H01L 25/18; H01L 24/08; H01L 24/14; H01L 24/16; H01L 2224/08145; H01L 2224/14153; H01L 2224/14155; H01L 2224/16227

(57) ABSTRACT

A opto-electronic assembly, including: a photonic integrated circuit (PIC), a radio frequency integrated circuit (RFIC), a substrate, and an interposer, wherein the RFIC is mounted on the PIC and is electrically connected to the PIC, wherein the PIC is mounted and electrically connected to the substrate via the interposer.

### FIELD OF THE DISCLOSURE

Various exemplary embodiments disclosed herein relate to a packaging architecture and methods for high signal integrity, compact and cost-effective photonic transceiver components.

### BACKGROUND

The ever-increasing demands for bandwidth in optical systems (data communications; telecommunications, both metro and long haul) entail advanced packaging schemes that can enable higher signal integrity for future generations of optical systems running at Baud rates above 100 GBd. Silicon Photonics integrated circuits (PICs) and high-speed Analog Radio Frequency integrated circuits RFICs may be integrated. This provides opportunities for unique approaches of advanced packaging, and co-design of PICs and RFICs for optimal high speed electrical and optical performance.

### SUMMARY

A summary of various exemplary embodiments is presented below.

Various embodiments relate to an opto-electronic assembly, including: a photonic integrated circuit (PIC); a radio frequency integrated circuit (RFIC); a substrate, and
an interposer, wherein the RFIC is mounted on the PIC and is electrically connected to the PIC, wherein the PIC is mounted and electrically connected to the substrate via the interposer.

Various embodiments are described, wherein the interposer includes a single piece with a through-hole opening.

Various embodiments are described, wherein the substrate includes a cavity, the substrate and the interposer together define a housing space, and the PIC and the RFIC are located at least partly inside the housing space.

Various embodiments are described, wherein the interposer has an opening that serves as the housing space.

Various embodiments are described, wherein the interposer has a surface oriented toward the PIC and the substrate, the surface overlaps partly with the PIC and partly with the substrate.

Various embodiments are described, wherein the interposer includes redistribution layers (RDLs) as horizontal interconnects between PIC connector pads and interposer connector pads.

Various embodiments are described, wherein each of the horizontal interconnects connects a plurality of the PIC connector pads with a plurality of substrate pads.

Various embodiments are described, wherein the RDLs within the PIC are used to connect the RFIC via the PIC connector pads to establish an electrical connection to the substrate.

Various embodiments are described, wherein at least some of the horizontal interconnects on the interposer are arranged geometrically in parallel.

Various embodiments are described, wherein the interposer includes a single or a stack of multiple RDLs, and the RDL including a plurality of electrically conductive lines.

Various embodiments are described, wherein the interposer further includes a single or multiple isolating layers, wherein the RDL is arranged between these isolating layers.

Various embodiments are described, wherein the interposer further includes a plurality of electrically conductive contact elements, and each of the electrically conductive contact elements traverses the isolating layers.

Various embodiments are described, wherein each of the electrically conductive contact elements connects one of the electrically conductive lines to one of a node on the substrate and a node on the PIC.

Further various embodiments relate to a method for assembling opto-electronic assembly, including a photonic integrated circuit (PIC), a radio frequency integrated circuit (RFIC), a substrate, and a interposer, including: bonding the RFICs to the PIC to form a first sub-assembly wherein the RFIC and PIC are electrically connected; bonding the first sub-assembly to the interposer to form a second sub-assembly wherein the PIC and the RFIC are electrically connected to the interposer; and bonding the second sub-assembly to the substrate wherein interposer is electrically connected to the substrate and wherein the substrate is electrically connected to the PIC and the RFICs via the interposer.

Various embodiments are described, wherein mounting the first sub-assembly to the interposer uses pick and place method and mass reflow in a standard flip chip process.

Various embodiments are described, wherein mounting the second sub-assembly to the substrate uses pick and place method and mass reflow in a standard flip chip process.

Various embodiments are described, wherein mounting the RFIC to the PIC uses a chip to wafer bonding process wherein the RFIC at chip level are bonded to the PIC at a wafer level.

Various embodiments are described, wherein mounting the RFIC to the PIC uses one of pick and place method and mass reflow in a standard flip chip process and pick and place and thermocompression process.

Various embodiments are described, wherein mounting the RFIC to the PIC uses a hybrid bonding process wherein the electrical connection is established using a direct Copper to Copper bond in conjunction with an oxide to oxide bond.

Further various embodiments relate to a method for assembling opto-electronic assembly, including a photonic integrated circuit (PIC), a radio frequency integrated circuit (RFIC), a substrate, and a interposer, including: bonding the RFIC and the interposer to the PIC to form a first sub-assembly wherein the RFIC and PIC and interposer are electrically connected; and bonding the first sub-assembly to the substrate wherein interposer is electrically connected to the substrate and wherein the substrate is electrically connected to the PIC via the interposer.

Various embodiments are described, wherein the interposer includes a first portion and a separate second portion.

Various embodiments are described, further including bonding RFIC and the interposer to a temporary carrier before mounting the RFIC and the interposer to the PIC; and removing the temporary carrier from the RFIC and the interposer after mounting the RFIC and the interposer to the PIC.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1A illustrates a circuit board with an RFIC mounted on a PIC.

FIG. 1B illustrates a cross-sectional view of the circuit board in FIG. 1A.

FIG. 2A provides a schematic representation of the circuit board using the interposer to provide a connection between the PIC and the substrate.

FIG. 2B illustrates a cross-sectional view of the circuit board.

FIGS. 3A and 3B illustrate a perspective and cross-sectional schematic representation of RFICs bonded on top of a PIC.

FIG. 4 provides a visual depiction of the assembly of the RFICs-PIC sub-assembly to the interposer of this stage.

FIGS. 5A-C illustrate cross-sectional, bottom, and top views of the combination of the RFICs-PIC sub-assembly and the interposer.

FIGS. 6A and 6B illustrate bottom and top views of a two piece interposer attached to a PIC.

FIG. 7A illustrates the interposer with some top layers removed to show the traces in the interposer.

FIG. 7B illustrates the interposer without interposer connectors.

FIGS. 7C and 7D illustrate cross-sectional and perspective views of the interposer with the interposer connectors.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Several aspects of a packaging architecture and methods for high signal integrity, compact and cost-effective photonic transceiver components will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

The ever-increasing demands for bandwidth in optical systems (data communications; telecommunications, both metro and long haul) entail advanced packaging schemes that can enable higher signal integrity for future generations of optical systems running at Baud rates above 100 GBd. Silicon Photonics integrated circuits (PICs) and high-speed Analog Radio Frequency integrated circuits RFICs may be integrated. This provides opportunities for unique approaches of advanced packaging, and co-design of PICs and RFICs for optimal high speed electrical and optical performance. Embodiments of an assembly approach/architecture that allows for high integrity signal interconnects between the substrate, PIC, and RFIC by minimizing parasitic inductance and capacitance typically experienced by substrate traces, multiple pads and/or wire-bonds will be described herein.

Presently, the assembly and packaging of coherent photonic transceivers rely primarily on conventional techniques such as Flip-chip and Wire-bonding.

With the growing need for higher bandwidth interconnects, it is important to explore alternative approaches that can effectively translate the high performance attained at the chip level to the module level by minimizing interconnect distance. The most critical signal integrity requirement arises between the PIC and RFICs. This can be addressed by reducing the interconnect length between these integrated circuits (ICs) down to the height of the connecting bump by bonding the RFICs on top of the PIC using Flip-chip processes. The interconnect parasitics can be further reduced with more advanced bonding techniques like hybrid bonding.

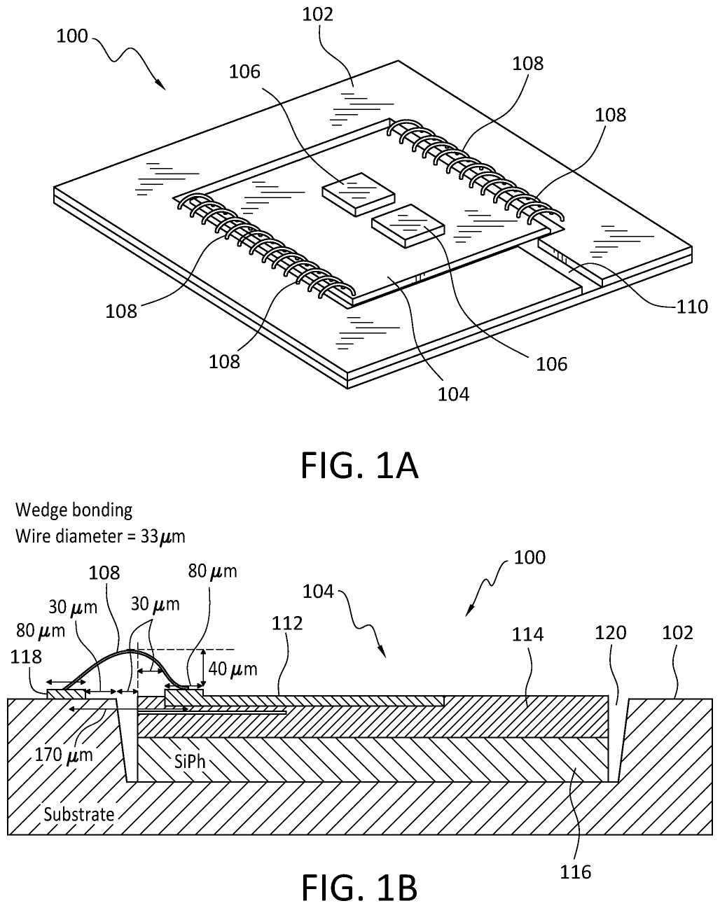

However, this approach requires multiple wire-bonded connections to bring all electrical signals—high speed, power supplies as well as controls—to the RFICs through the PIC. FIG. 1A illustrates an example of a circuit board 100 with an RFIC mounted on a PIC. FIG. 1B illustrates a cross-sectional view of the circuit board 100 in FIG. 1A. The circuit board 100 includes two RFICs 106 mounted and connected to a PIC 104. The circuit board 100 includes a substrate 102. The PIC 104 is mounted to the substrate 102 in a substrate cavity 120. The substrate 102 also includes an optical connector channel 110 that allows an optical connector (not shown) to connect to the PIC 104. The PIC 104 is connected to substrate pads 118 on substrate 102 via wire-bonds 108. The substrate 102 connects to PIC pads 112 on the PIC 104. The PIC 104 may include upper PIC substrate 114 and lower PIC substrate 116.

Therefore, in order to exploit the high signal integrity of stacking the RFIC 106 above the PIC 104 as described above requires maintaining the signal integrity across wire-bonds 108. Mass production of transceivers with wire-bonds supporting 100 Gbd+ signals require: repeatably producing very short ˜100-150 um wire-bonds; well controlled matching of the height of the PIC and substrate to enable connections with such short wire-bonds; this, in turn, requires tight manufacturing tolerances of the substrate cavity 120 in the substrate, into which the PICs 104 may be placed. Furthermore, short wire-bonds 108 also entail short distances from the substrate pad 118 on the substrate to the PIC pad 112 on the PIC. This may require manufacturing of substrate cavities with almost perfect vertical walls. FIG. 1A illustrates these manufacturing tolerances. As can be seen, best case wire-bond lengths easily exceed 170 um (without the loop), which can lead to high parasitic inductances in the signal path. Wedge bonding with a wire diameter of 33 um is illustrated in FIG. 1A.

A goal of the embodiments described herein is to minimize the interconnect length between the PIC 104, and RFICs 106, while simultaneously maintaining a high integrity path from the substrate 102, while eliminating the difficulties in manufacturing high speed products with wire-bonds 108.

To achieve this goal, a face-to-face bonding technique may be utilized, where the RFICs are bonded on top of the PIC. This bonding can be accomplished through standard flip-chip methods employing solder bumps, or alternatively, a solderless option such as hybrid bonding.

However, the embodiment disclosed herein uses a packaging architecture different from the wire-bonds 108 as a connection to the substrate 102. An interposer is employed to connect the PIC to the substrate, offering scalability, while keeping the RFICs exposed from the top side for efficient cooling with a typical heat-sink arrangement. The interposer may also be called a mounting piece.

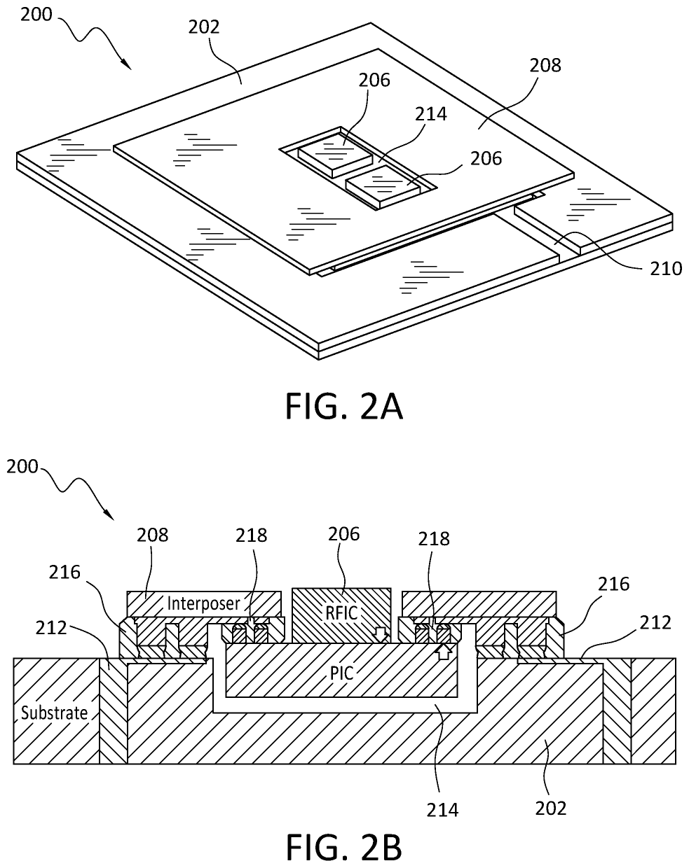

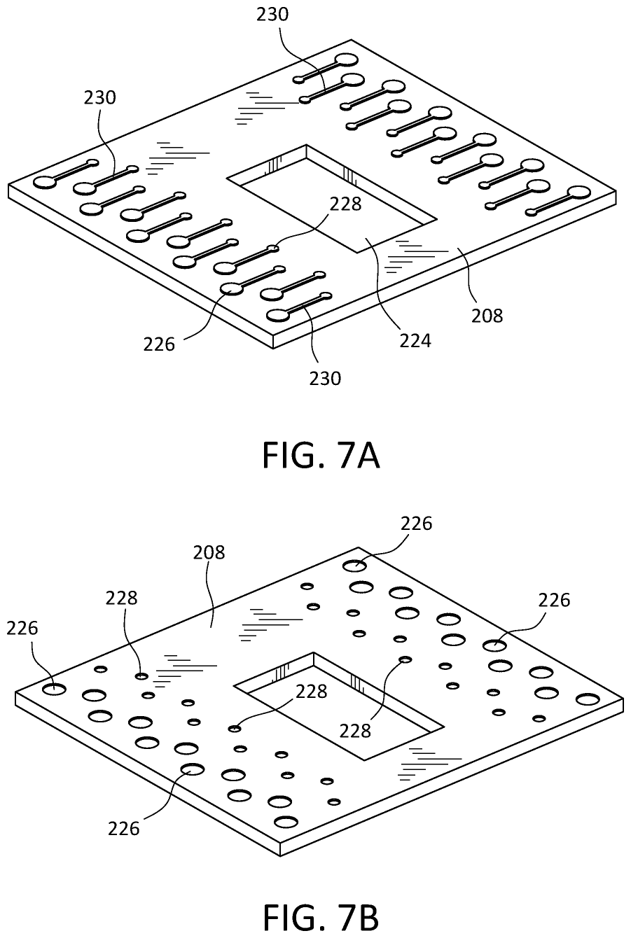

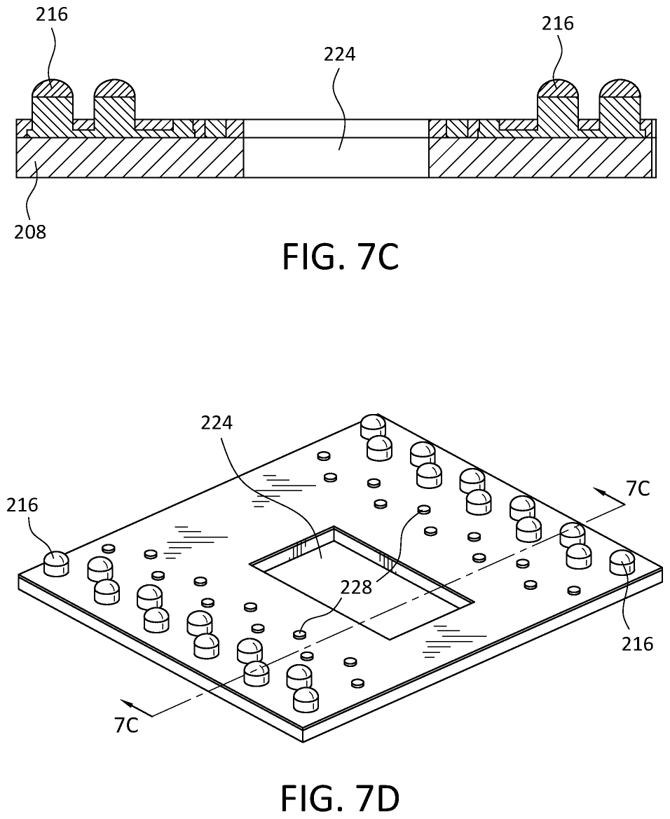

FIG. 2A provides a schematic representation of the circuit board 200 using the interposer to provide a connection between the PIC and the substrate. FIG. 2B illustrates a cross-sectional view of the circuit board 200. The circuit board 200 includes RFICs 206, PIC 204, and substrate 202 as before in FIG. 1. The interposer 208 connects the PIC 204 to the substrate 202. The interposer 208 may be generally plate-shaped or ring-shaped. This connection is facilitated by interposer connectors 216 and PIC connectors 218. The interposer connectors 216 may be formed on and extend from the interposer 208. The interposer connectors 216 may be manufactured using standard chip manufacturing processes. The interposer 208 may include interposer trace lines 230 (see FIG. 7A) that connect the interposer connectors 216 to the PIC connector 218.

The interposer 208 could be one of many different materials: ceramic; High Density Build-Up (HDBU) Substrate; silicon, or glass, with features defined using standard CMOS backend processes. The use of silicon or glass could open various other embodiments enabling co-packaging of ICs from different technologies.

The interposer 208 may have a first surface that is oriented towards the substrate cavity 214 and the substrate 202. The interposer connector 216 may be on this first surface. The interposer connector 216 connects to the substrate pad 212. Further, the first surface partly overlaps with the substrate cavity 214 and partly overlaps with the substrate 202 in order to facilitate the connections between the interposer 208 and the substrate 202 and substrate cavity 214.

The circuit board 200 proposed may be constructed in multiple stages. The following description presents the stages in a sequential order, accompanied by a brief discussion on potential implementation approaches.

A first stage may include the assembly of the RFICs 206 to the PIC 204. In this stage, the bonding of the RFICs 206 onto the PIC 204 occurs. This bonding process can be accomplished through a standard flip-chip technique utilizing solder bumps (or Cu pillars with Sn cap) for chip-to-chip connections. All components come singulated into individual dies and are later assembled using mass reflow. To reinforce the assembly, an underfill material is then applied and cured.

Alternatively, a slightly different approach involves thermo-compression with pre-applied underfill, although this option has a lower throughput.

Another more advanced bonding method for the RFICs and the PIC is hybrid bonding. This technique involves using oxide-to-oxide bonding for adhesion between the dies, while Cu pads on the bonded chips ensure electrical interconnectivity.

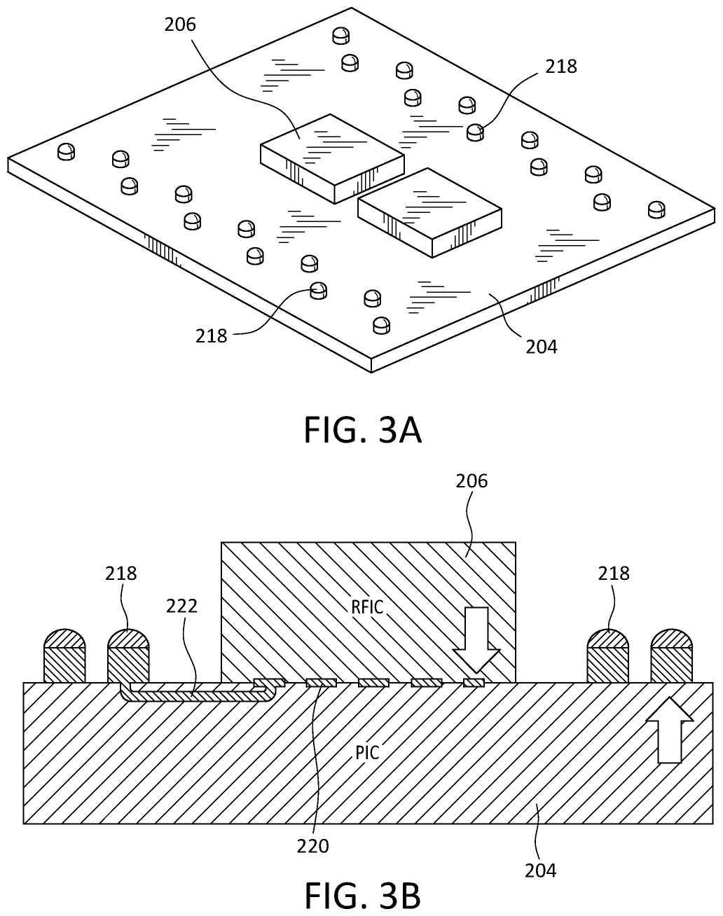

FIGS. 3A and 3B illustrate a perspective and cross-sectional schematic representation of RFICs 206 bonded on top of a PIC 204. The PIC 204 may have multiple PIC connectors 218 arranged in any fashion and number needed to accommodate the connections between the PIC 204 and interposer 208.

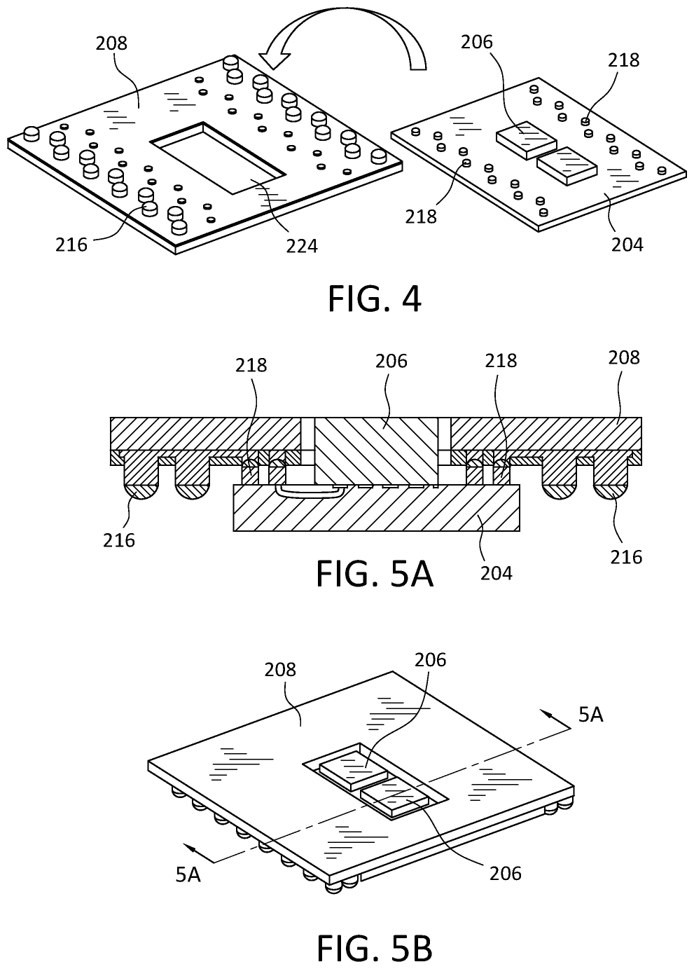

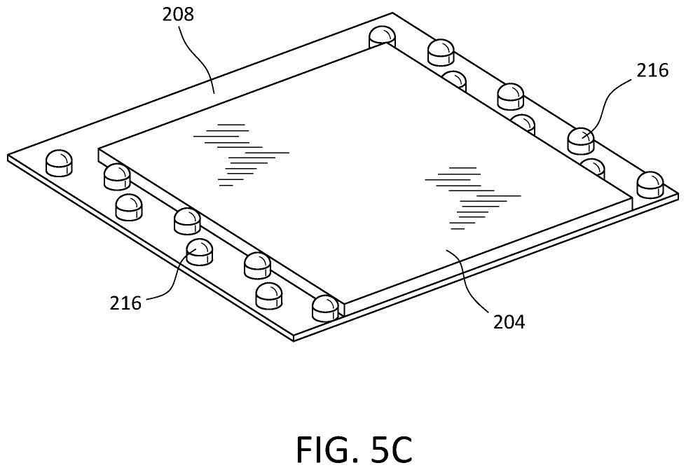

A second assembly stage may include the assembly of the PIC-RFICs sub-assembly to the interposer 208. In this stage, the sub-assembly including the PIC and RFICs is mounted onto the interposer 208. The interposer 208 is designed with a interposer opening 224 that accommodates all the assembled RFICs 206. This interposer opening 224 exposes the backside of these dies for cooling purposes. The assembly process can utilize either standard pick-and-place and mass reflow techniques or thermocompression techniques. Mass reflow is preferred for better manufacturability, but careful control of the capillary underfill is essential to prevent overflowing into the cut-out area. Thermocompression, on the other hand, involves pre-applied underfill but may have a lower throughput impact, which can be evaluated for this stage to make sure that the critical facet area is not contaminated. FIG. 4 provides a visual depiction of the assembly of the RFICs-PIC sub-assembly to the interposer 208 of this stage. FIGS. 5A-C illustrated cross-sectional, bottom, and top views of the combination of the RFICs-PIC sub-assembly and the interposer 208.

In a scenario where the interposer is silicon or glass, and the standard flip chip technique is used, a pick and place process may be used to place the RFICs as well as the interposer on top of the PIC and complete the flip-chip process by reflowing them all at the same step.

An alternative process to avoid alignment and movement risks between the pick-and-place to the reflow steps, would include mounting the interposer 208 and the RFIC 206 dies on a temporary carrier and to perform the flip-chip of the PIC 204 on top of the interposer 208 and RFICs 206, having in mind that the temporary carrier thermal budget must be compatible with the flip chip attach.

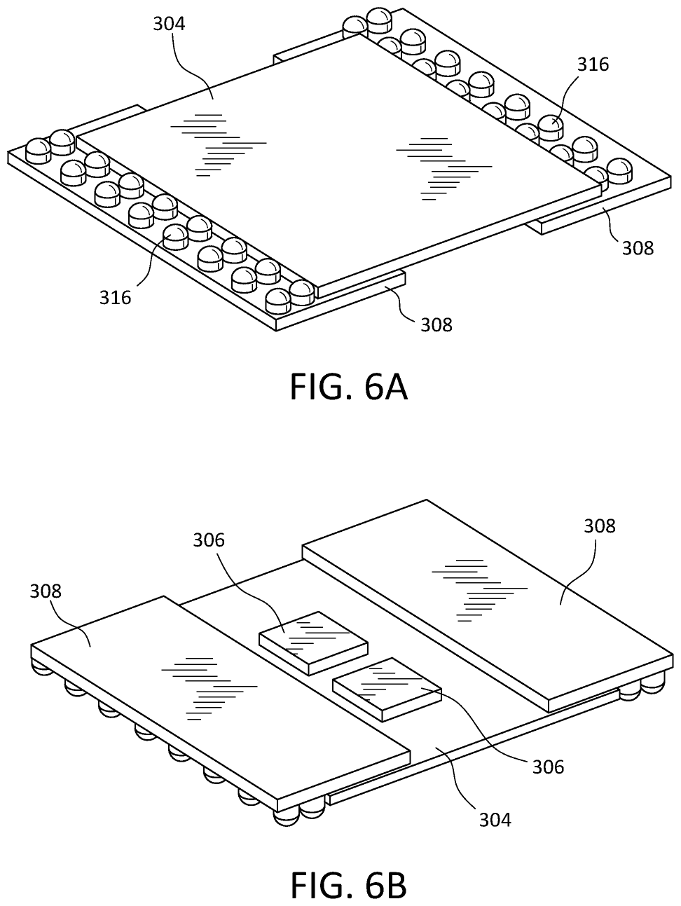

However, another option could be that the interposer 208 is replaced by two smaller silicon or glass dies, which can then go through reflow along with the RFICs 206. FIGS. 6A and 6B illustrate bottom and top views of a two piece interposer attached to a PIC 204. In this case, the interposer 308 is a bridge die between the PIC 204 and substrate 202. The interposer 308 may be made of the same materials as the interposer 208 previously described.

FIG. 7A illustrates the interposer 208 with some top layers removed to show the traces in the interposer 208. Interposer trace lines 230 connect PIC connector pad 228 to interposer connector pad 226. In FIG. 7A the interposer trace lines 230 are shown as being arranged geometrically in parallel. Further, the interposer trace lines 230 may be part of a redistribution layer (RDL) that distributes electrical signals. The PIC connector pad 228 and interposer connector pad 226 and any other connector pads in the circuit board 200 may also be nodes. These nodes include points of conductive structures that facilitate electrical connections. The PIC connector pad 228 connects to interposer connector 216. The interposer connector pad 226 connects to PIC connector 218. FIG. 7B illustrates the interposer 208 without interposer connectors 216. In this view the interposer connector pad 226 and PIC connector pad 228 are visible, but the interposer trace lines 230 are not visible as they are under the top layers of the interposer 208. This top layer and other layers of the interposer 208 may be isolating layers that isolate conductive layers from one another. FIGS. 7C and 7D illustrate cross-sectional and perspective views of the interposer 208 with the interposer connectors 216.

The next stage of attaching the interposer-PIC-RFIC sub-assembly to the substrate will now be described. Once the PIC-RFIC sub-assembly is mounted onto the interposer 208, it is flipped and mounted onto the substrate 202 to establish its interconnection with the rest of the module. This assembly step can be carried out using standard pick-and-place and mass reflow techniques. In a first embodiment, the substrate itself incorporates a square cavity to accommodate the PIC 204. FIG. 2A illustrates the final assembled circuit board 200 where the interposer-PIC-RFIC sub-assembly has been assembled with the substrate.

It is noted that the substrate 202 has a substrate cavity 214 that accepts the substrate cavity 214 therein. Further, the substrate cavity 214 in the substrate 202 along with the interposer 208 form an inner space, and the substrate cavity 214 and RFICs 206 are located completely within or partially within this inner space.

In a different embodiment, the pillars or ball grid arrays (BGAs) between the interposer 208 and the substrate 202 have sufficient height that can leave enough space to accommodate a thinned PIC 204 die. This situation alleviates the necessity of having the substrate cavity 214 within the substrate 202.

It is worth noting that depending on the product's requirements, the substrate can also accommodate a switch or Digital Signal Processor Application-Specific Integrated Circuit (DSP ASIC) in addition to the PIC and RFIC. This integration of the ASIC helps reduce the overall size of the module or the final product.

The foregoing disclosure provides illustration and description but is not intended to be exhaustive or to limit the aspects to the precise form disclosed. Modifications and variations may be made in light of the above disclosure or may be acquired from practice of the aspects.

As used herein, the term “component” is intended to be broadly construed as hardware, firmware, and/or a combination of hardware and software. As used herein, a processor is implemented in hardware, firmware, and/or a combination of hardware and software.

As used herein, satisfying a threshold may, depending on the context, refer to a value being greater than the threshold, greater than or equal to the threshold, less than the threshold, less than or equal to the threshold, equal to the threshold, not equal to the threshold, and/or the like. It will be apparent that systems and/or methods described herein may be implemented in different forms of hardware, firmware, and/or a combination of hardware and software. The actual specialized control hardware or software code used to implement these systems and/or methods is not limiting of the aspects. Thus, the operation and behavior of the systems and/or methods were described herein without reference to specific software code—it being understood that software and hardware can be designed to implement the systems and/or methods based, at least in part, on the description herein.

As used herein, the term “non-transitory machine-readable storage medium” will be understood to exclude a transitory propagation signal but to include all forms of volatile and non-volatile memory. When software is implemented on a processor, the combination of software and processor becomes a specific dedicated machine.

Because the data processing implementing the embodiments described herein is, for the most part, composed of electronic components and circuits known to those skilled in the art, circuit details will not be explained in any greater extent than that considered necessary as illustrated above, for the understanding and appreciation of the underlying concepts of the aspects described herein and in order not to obfuscate or distract from the teachings of the aspects described herein.

Unless stated otherwise, terms such as “first” and “second” are used to arbitrarily distinguish between the elements such terms describe. Thus, these terms are not necessarily intended to indicate temporal or other prioritization of such elements.

It should be appreciated by those skilled in the art that any block diagrams herein represent conceptual views of illustrative hardware embodying the principles of the aspects.

While each of the embodiments are described above in terms of their structural arrangements, it should be appreciated that the aspects also cover the associated methods of using the embodiments described above.

Unless otherwise indicated, all numbers expressing parameter values and so forth used in the specification and claims are to be understood as being modified in all instances by the term “about.” Accordingly, unless indicated to the contrary, the numerical parameters set forth in this specification and attached claims are approximations that may vary depending upon the desired properties sought to be obtained by embodiments of the present disclosure. As used herein, “about” may be understood by persons of ordinary skill in the art and can vary to some extent depending upon the context in which it is used. If there are uses of the term which are not clear to persons of ordinary skill in the art, given the context in which it is used, “about” may mean up to plus or minus 10% of the particular term.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Furthermore, as used herein, the terms “set” and “group” are intended to include one or more items (e.g., related items, unrelated items, a combination of related and unrelated items, and/or the like), and may be used interchangeably with “one or more.” Where only one item is intended, the phrase “only one” or similar language is used. Also, as used herein, the terms “has,” “have,” “having,” and/or the like are intended to be open-ended terms. Further, the phrase “based on” is intended to mean “based, at least in part, on” unless explicitly stated otherwise.

1. An opto-electronic assembly, comprising:
a photonic integrated circuit (PIC);
a radio frequency integrated circuit (RFIC);
a substrate, and
an interposer,
wherein the RFIC is mounted on the PIC and is electrically connected to the PIC,
wherein the PIC is mounted and electrically connected to the substrate via the interposer.

2. The opto-electronic assembly of claim 1, wherein the interposer includes a single piece with a through-hole opening.

3. The opto-electronic assembly of claim 1, wherein
the substrate includes a cavity,
the substrate and the interposer together define a housing space, and
the PIC and the RFIC are located at least partly inside the housing space.

4. The opto-electronic assembly of claim 1, wherein the interposer has an opening that serves as the housing space.

5. The opto-electronic assembly of claim 1, wherein the interposer has a surface oriented toward the PIC and the substrate, the surface overlaps partly with the PIC and partly with the substrate.

6. The opto-electronic assembly of claim 1, wherein the interposer comprises redistribution layers (RDLs) as horizontal interconnects between PIC connector pads and interposer connector pads.

7. The opto-electronic assembly of claim 6, wherein each of the horizontal interconnects connects a plurality of the PIC connector pads with a plurality of substrate pads.

8. The opto-electronic assembly of claim 6, wherein the RDLs within the PIC are used to connect the RFIC via the PIC connector pads to establish an electrical connection to the substrate.

9. The opto-electronic assembly of claim 6, wherein at least some of the horizontal interconnects on the interposer are arranged geometrically in parallel.

10. The opto-electronic assembly of claim 6, wherein
the interposer comprises at least one of the following:
a single RDL comprising a plurality of electrically conductive lines; and
a stack of multiple RDLs, each RDL of the stack comprising a plurality of electrically conductive lines.

11. The opto-electronic assembly of claim 10, wherein the interposer further comprises a single or multiple isolating layers, wherein the RDL is arranged between these isolating layers.

12. The opto-electronic assembly of claim 11, wherein
the interposer further comprises a plurality of electrically conductive contact elements, and
each of the electrically conductive contact elements traverses the isolating layers.

13. The opto-electronic assembly of claim 12, wherein each of the electrically conductive contact elements connects one of the electrically conductive lines to one of a node on the substrate and a node on the PIC.

14. A method for assembling opto-electronic assembly, comprising a photonic integrated circuit (PIC), a radio frequency integrated circuit (RFIC), a substrate, and
an interposer, comprising:
bonding the RFICs to the PIC to form a first sub-assembly wherein the RFIC and the PIC are electrically connected;
bonding the first sub-assembly to the interposer to form a second sub-assembly wherein the PIC and the RFIC are electrically connected to the interposer; and
bonding the second sub-assembly to the substrate wherein the interposer is electrically connected to the substrate and wherein the substrate is electrically connected to the PIC and the RFICs via the interposer.

15. The method of claim 14, wherein mounting the first sub-assembly to the interposer uses a pick and place method and mass reflow in a flip chip process.

16. The method of claim 14, wherein mounting the second sub-assembly to the substrate uses pick and place method and mass reflow in a standard flip chip process.

17. The method of claim 14, wherein mounting the RFIC to the PIC uses a chip to wafer bonding process wherein the RFIC at chip level are bonded to the PIC at a wafer level.

18. The method of claim 17, wherein mounting the RFIC to the PIC uses one of pick and place method and mass reflow in a standard flip chip process and pick and place and thermocompression process.

19. The method of claim 17, wherein mounting the RFIC to the PIC uses a hybrid bonding process wherein the electrical connection is established using a direct Copper to Copper bond in conjunction with an oxide to oxide bond.

20. A method for assembling opto-electronic assembly, comprising a photonic integrated circuit (PIC), a radio frequency integrated circuit (RFIC), a substrate, and
an interposer, comprising:
bonding the RFIC and the interposer to the PIC to form a first sub-assembly wherein the RFIC and the PIC and the interposer are electrically connected; and
bonding the first sub-assembly to the substrate wherein the interposer is electrically connected to the substrate and wherein the substrate is electrically connected to the PIC via the interposer.

21. The method of claim 20, wherein the interposer includes a first portion and a separate second portion.

22. The method of claim 20, further comprising
bonding the RFIC and the interposer to a temporary carrier before mounting the RFIC and the interposer to the PIC; and
removing the temporary carrier from the RFIC and the interposer after mounting the RFIC and the interposer to the PIC.
